(19) United States
(12) Patent Application Publication
(10) Pub. No.: US 2024/0389374 A1
(43) Pub. Date: Nov. 21, 2024

(54) QUANTUM DOT LIGHT EMITTING DEVICE AND MANUFACTURING METHOD THEREFOR, DISPLAY PANEL, AND DISPLAY APPARATUS

(71) Applicants: Beijing BOE Technology Development Co., Ltd., Beijing (CN); BOE Technology Group Co., Ltd., Beijing (CN)

(72) Inventor: Dong LI, Beijing (CN)

(21) Appl. No.: 18/578,670

(22) PCT Filed: Aug. 26, 2021
(86) PCT No.: PCT/CN2021/114788

§ 371 Date: Jan. 11, 2024

(51) Int. Cl. H10K 50/115; B82Y 20/00; B82Y 40/00; C09D 5/22; H10K 71/12; H10K 85/10; H10K 85/60; H10K 102/00

(52) U.S. Cl. CPC H10K 50/115; C09D 5/22; H10K 71/12; H10K 85/115; H10K 85/141; H10K 85/151; H10K 85/626; H10K 85/6572; B82Y 20/00; B82Y 40/00; H10K 2102/351

(57) ABSTRACT

Disclosed are a quantum dot light emitting device and a manufacturing method therefor, a display panel and a display apparatus. The quantum dot light emitting device includes: a substrate; a first electrode located on one side of the substrate; a first transport layer located on the side of the first electrode facing away from the substrate, wherein the surface of the side of the first transport layer facing away from the first electrode has a bump shape; a polymer quantum dot layer which is located on the side of the first transport layer facing away from the first electrode and includes a polymer material and a quantum dot material; and a second electrode located on the side of the polymer quantum dot layer facing away from the first transport layer.

### CROSS-REFERENCE TO RELATED APPLICATIONS

The present application is a National Stage of International Application No. PCT/CN2021/114788, filed Aug. 26, 2021, the entire content of which is hereby incorporated by reference.

### TECHNICAL FIELD

The present disclosure relates to the technical field of display, and particularly relates to a quantum dot light emitting device and a manufacturing method therefor, a display panel and a display apparatus.

### BACKGROUND

Quantum dots, a type of novel light emitting materials, feature high light color purity, high light emitting quantum efficiency, adjustable light emitting colors and long service life, and therefore have become a hot research topic of novel light emitting diode light emitting materials. Accordingly, quantum dot light emitting diodes (QLEDs) with quantum dot materials as light emitting layers have become a dominant research direction of novel display devices.

### SUMMARY

Embodiments of the present disclosure provide a quantum dot light emitting device. The quantum dot light emitting device includes:
a substrate;
a first electrode located on a side of the substrate;
a first transport layer located on a side of the first electrode facing away from the substrate; where a surface of a side of the first transport layer facing away from the first electrode has a bump shape;
a polymer quantum dot layer which is located on the side of the first transport layer facing away from the first electrode and includes a polymer material and a quantum dot material; and
a second electrode located on a side of the polymer quantum dot layer facing away from the first transport layer.

In some embodiments, root-mean-square surface roughness of a surface of a side of the polymer quantum dot layer facing away from the substrate is less than root-mean-square surface roughness of a surface of a side of the first transport layer facing away from the substrate.

In some embodiments, the root-mean-square surface roughness of the surface of the side of the first transport layer facing away from the substrate is greater than or equal to 5 nanometers and less than or equal to 15 nanometers.

In some embodiments, the surface of the side of the first transport layer facing away from the first electrode has a plurality of bump shapes.

A height of the bump shape is greater than or equal to 10 nanometers and less than or equal to 50 nanometers.

In some embodiments, root-mean-square surface roughness of a surface of the side of the polymer quantum dot layer facing away from the first transport layer is greater than or equal to 0.59 nanometer and less than or equal to 2.25 nanometers.

In some embodiments, the polymer material and the quantum dot material are located in the same film layer.

In some embodiments, a mass fraction of the polymer material in the polymer quantum dot layer is greater than or equal to 0.02% and less than or equal to 0.5%.

In some embodiments, a thickness of the polymer quantum dot layer is greater than or equal to 20 nanometers and less than or equal to 50 nanometers.

In some embodiments, the polymer quantum dot layer includes a polymer sub-layer including the polymer material and a quantum dot sub-layer including the quantum dot material, which are stacked.

In some embodiments, the polymer sub-layer is located between the quantum dot sub-layer and the first transport layer.

In some embodiments, the quantum dot sub-layer is located between the polymer sub-layer and the first transport layer.

In some embodiments, a mass fraction of the polymer material in the polymer sub-layer is greater than or equal to 0.02% and less than or equal to 0.5%.

In some embodiments, a thickness of the polymer sub-layer is greater than or equal to 20 nanometers and less than or equal to 50 nanometers.

A thickness of the quantum dot sub-layer is greater than or equal to 20 nanometers and less than or equal to 50 nanometers.

In some embodiments, a dipole is provided in a molecule of the polymer material.

In some embodiments, the polymer material includes one or a combination of polyethyleneimine ethoxylated, 2-methoxy-N-(3-methyl-2-oxo-1,2,3,4-tetrahydroquinazolin-6-yl) benzene sulfonamide, 9,9-dioctyl fluorene-9,9-bis(N,N-dimethylaminopropyl) fluorene, poly(9,9-di-octylfluorenyl-2,7-diyl), polymethyl methacrylate and polystyrene.

In some embodiments, a band gap of the polymer material is greater than 3.5 electronvolts.

In some embodiments, the first transport layer includes an electron transport layer.

The quantum dot light emitting device further includes a hole transport layer located between the polymer quantum dot layer and the second electrode, and a hole injection layer located between the hole transport layer and the second electrode.

In some embodiments, the first transport layer includes the hole transport layer.

The quantum dot light emitting device further includes an electron transport layer located between the polymer quantum dot layer and the second electrode, and a hole injection layer located between the hole transport layer and the first electrode.

In some embodiments, the polymer material is in contact with the electron transport layer and the hole transport layer in areas of at least some bump shapes.

Embodiments of the present disclosure provide a manufacturing method for a quantum dot light emitting device. The method includes:
providing a substrate and forming a first electrode on the substrate;
forming a first transport layer on a side of the first electrode facing away from the substrate through a sputtering process; where a surface of a side of the first transport layer facing away from the first electrode has a bump shape;
forming a polymer quantum dot layer on the side of the first transport layer facing away from the first electrode; where the polymer quantum dot layer includes a polymer material and a quantum dot material; and
forming a second electrode on a side of the polymer quantum dot layer facing away from the first transport layer.

In some embodiments, the forming a polymer quantum dot layer on the side of the first transport layer facing away from the first electrode includes:
providing the polymer material and the quantum dot material, and mixing the polymer material and the quantum dot material; and
depositing the polymer material and the quantum dot material that are mixed on the side of the first transport layer facing away from the first electrode, and forming the polymer quantum dot layer.

In some embodiments, the forming a polymer quantum dot layer on the side of the first transport layer facing away from the first electrode includes:
providing the polymer material, dissolving the polymer material in a solvent, and obtaining a polymer solution;
coating the side of the first transport layer facing away from the first electrode with the polymer solution, and forming a polymer sub-layer and
depositing the quantum dot material on a side of the polymer sub-layer facing away from the first transport layer and forming a quantum dot sub-layer.

In some embodiments, the forming a polymer quantum dot layer on the side of the first transport layer facing away from the first electrode includes:
depositing the quantum dot material on the side of the first transport layer facing away from the first electrode, and forming a quantum dot sub-layer;
dissolving the polymer material in a solvent, and obtaining a polymer solution; and
coating a side of the quantum dot sub-layer facing away from the first transport layer with the polymer solution, and forming a polymer sub-layer.

Embodiments of the present disclosure provide a display panel. The display panel includes a plurality of quantum dot light emitting devices provided in embodiments of the present disclosure.

Embodiments of the present disclosure provide a display apparatus. The display apparatus includes the display panel provided in embodiments of the present disclosure.

### BRIEF DESCRIPTION OF FIGURES

In order to describe technical solutions in embodiments of the present disclosure more clearly, accompanying drawings required to describe the embodiments will be briefly introduced below. Apparently, accompanying drawings in the following description show merely some embodiments of the present disclosure, and those of ordinary skill in the art would also be able to derive other accompanying drawings from these accompanying drawings without making creative efforts.

FIG. 1 is a schematic structural diagram of a quantum dot light emitting device according to an embodiment of the present disclosure.

FIG. 2 is a schematic structural diagram of another quantum dot light emitting device according to an embodiment of the present disclosure.

FIG. 3 is a schematic structural diagram of yet another quantum dot light emitting device according to an embodiment of the present disclosure.

FIG. 4 is a schematic structural diagram of yet another quantum dot light emitting device according to an embodiment of the present disclosure.

FIG. 5 is a schematic structural diagram of yet another quantum dot light emitting device according to an embodiment of the present disclosure.

FIG. 6 is a schematic structural diagram of yet another quantum dot light emitting device according to an embodiment of the present disclosure.

FIG. 7 is a schematic structural diagram of yet another quantum dot light emitting device according to an embodiment of the present disclosure.

FIG. 8 is a schematic structural diagram of yet another quantum dot light emitting device according to an embodiment of the present disclosure.

FIG. 9 is a schematic structural diagram of still another quantum dot light emitting device according to an embodiment of the present disclosure.

FIG. 10 is a schematic diagram of surface appearance of an electron transport layer of a quantum dot light emitting device according to an embodiment of the present disclosure.

FIG. 11 is a schematic diagram of surface appearance of a quantum dot layer of a quantum dot light emitting device according to the related art.

FIG. 12 is a schematic diagram of surface appearance of a polymer quantum dot layer of a quantum dot light emitting device according to an embodiment of the present disclosure.

FIG. 13 is a schematic diagram of surface appearance of a polymer quantum dot layer of another quantum dot light emitting device according to an embodiment of the present disclosure.

FIG. 14 is a schematic diagram of surface appearance of a polymer quantum dot layer of yet another quantum dot light emitting device according to an embodiment of the present disclosure.

FIG. 15 is a diagram showing voltage-current density curves of a plurality of quantum dot light emitting devices according to an embodiment of the present disclosure.

FIG. 16 is a diagram showing voltage-current efficiency curves of a plurality of quantum dot light emitting devices according to an embodiment of the present disclosure.

FIG. 17 is another diagram showing voltage-current density curves of a plurality of quantum dot light emitting devices according to an embodiment of the present disclosure.

FIG. 18 is yet another diagram showing voltage-current efficiency curves of a plurality of quantum dot light emitting devices according to an embodiment of the present disclosure.

FIG. 19 is a schematic flow diagram of a manufacturing method for a quantum dot light emitting device according to an embodiment of the present disclosure.

### DETAILED DESCRIPTION

In order to make objectives, technical solutions and advantages of embodiments of the present disclosure clearer, technical solutions in the embodiments of the present disclosure will be clearly and completely described below in combination with accompanying drawings in the embodiments of the present disclosure. Apparently, the described embodiments are merely some embodiments rather than all embodiments of the present disclosure. In addition, embodiments of the present disclosure and features in the embodiments can be combined with one another without conflict. On the basis of the described embodiments of the present disclosure, all other embodiments derived by those of ordinary skill in the art without making creative efforts all fall within the scope of protection of the present disclosure.

Unless otherwise defined, technical terms or scientific terms used in the present disclosure should have the ordinary meanings understood by those of ordinary skill in the art to which the present disclosure belongs. “First”, “second” and other similar words used in the present disclosure do not indicate any order, quantity or importance, but are merely used to distinguish between different components. “Comprise”, “include” and other similar words mean that an element or object appearing before the word contains elements or objects listed after the word and their equivalents, without excluding other elements or objects. “Connection”, “connected” and other similar words are not limited to physical or mechanical connections, but can include electrical connections, whether direct or indirect.

It should be noted that sizes and shapes of all figures in accompanying drawings do not reflect true scales and are merely intended to illustrate content of the present disclosure. Moreover, the same or similar reference numerals denote the same or similar elements or elements having the same or similar functions throughout.

In the related art, it can be seen through experiments that in an inverted structure of a quantum dot light emitting diode (QLED) device, in a case that a sputtering-type zinc oxide (ZnO) thin film is taken as a first transport layer quantum dots are directly deposited on ZnO. Since adhesion between the quantum dots and ZnO is small, the quantum dots are not easy to deposit on a ZnO surface. Thus, the film is likely to be loosened and even a large pin-hole is likely to occur, resulting in a large leakage current of the device. Moreover, plenty of bumps can be seen on a surface of a ZnO thin film formed through sputtering. ZnO has high electronic conductivity, and a large number of electrons are injected into the first transport layer and enriched at interfaces between the first transport layer and the quantum dots. Thus, carrier balance of the device is affected, and light emitting efficiency of the device is affected.

On the basis of the above problems in the related art, embodiments of the present disclosure provide a quantum dot light emitting device.

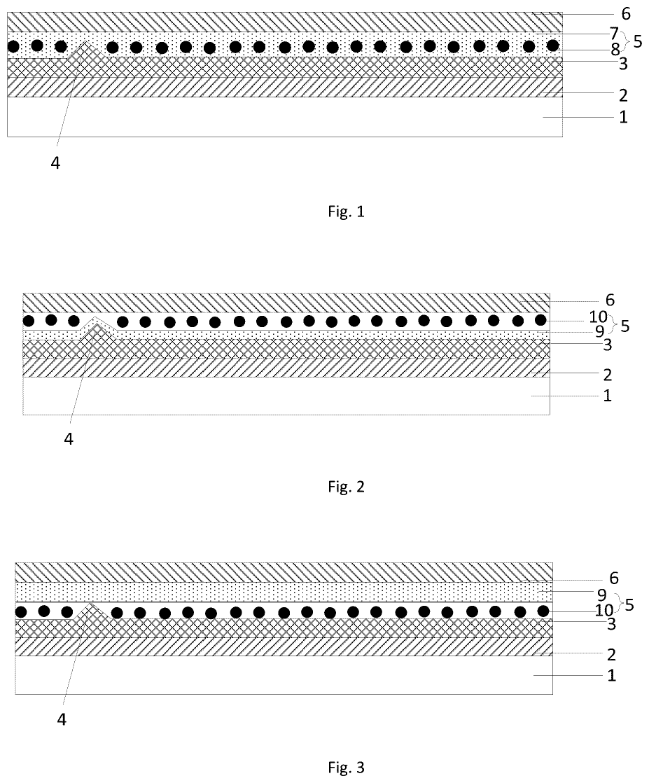

As shown in FIG. 1, the quantum dot light emitting device includes:
a substrate 1;
a first electrode 2 located on a side of the substrate 1;
a first transport layer 3 located on a side of the first electrode 2 facing away from the substrate 1; where a surface of a side of the first transport layer 3 facing away from the first electrode 2 has a bump 4 shape;
a polymer quantum dot layer 5, which is located on the side of the first transport layer 3 facing away from the first electrode 2 and includes a polymer material 7 and a quantum dot material 8; and
a second electrode 6 located on a side of the polymer quantum dot layer 5 facing away from the first transport layer 3.

Since the quantum dot light emitting device provided in embodiments of the present disclosure includes the polymer quantum dot layer and the polymer material of the polymer quantum dot layer can cover the bump shape on the surface of the first transport layer a large leakage current of the quantum dot light emitting device caused by looseness of a quantum dot film layer in a case that only the quantum dot film layer is arranged is avoided. Thus, carrier balance of the quantum dot light emitting device can be improved, and light emitting efficiency of the quantum dot light emitting device can be increased.

It should be noted that in FIG. 1, only one bump shape on the surface of the first transport layer is taken as an example for illustration. Due to process conditions, the surface of the first transport layer formed on the side of the first electrode facing away from the substrate is uneven and has a plurality of bump shapes. During implementations, the first transport layer is formed on the side of the first electrode facing away from the substrate through a sputtering process, for example.

In some embodiments, as shown in FIG. 1, the polymer material 7 and the quantum dot material 8 are located on the same film layer in the polymer quantum dot layer 5.

In some embodiments, the polymer material and the quantum dot material are uniformly mixed.

In this way, the polymer material can fill gaps of quantum dots, such that a large leakage current of the quantum dot light emitting device is avoided. Thus, carrier balance of the quantum dot light emitting device can be improved, and light emitting efficiency of the quantum dot light emitting device can be increased.

In a case that the polymer material and the quantum dot material are uniformly mixed, in some embodiments, a mass fraction of the polymer material in the polymer quantum dot layer is greater than or equal to 0.02% and less than or equal to 0.5%.

In a case that the polymer material and the quantum dot material are uniformly mixed, in some embodiments, a thickness of the polymer quantum dot layer is greater than or equal to 20 nanometers and less than or equal to 50 nanometers.

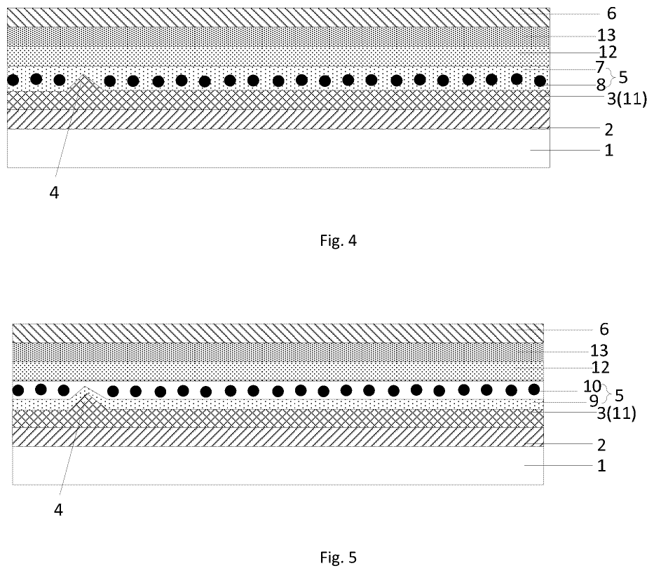

Alternatively, in some embodiments, as shown in FIGS. 2 and 3, the polymer quantum dot layer 5 includes a polymer sub-layer 9 including the polymer material and a quantum dot sub-layer 10 including the quantum dot material, which are stacked.

That is a film layer including the polymer material and a film layer including the quantum dot material are manufactured separately. In this way, the polymer sub-layer including the polymer material can fill a gap of the quantum dot sub-layer such that a large leakage current of the quantum dot light emitting device caused by transmission of the quantum dot sub-layer is avoided. Thus, carrier balance of the quantum dot light emitting device can be improved, and light emitting efficiency of the quantum dot light emitting device can be increased.

In some embodiments, as shown in FIG. 2, the polymer sub-layer 9 is located between the quantum dot sub-layer 10 and the first transport layer 3.

In some embodiments, as shown in FIG. 3, the quantum dot sub-layer 10 is located between the polymer sub-layer 9 and the first transport layer 3.

In some embodiments, a mass fraction of the polymer material in the polymer sub-layer is greater than or equal to 0.02% and less than or equal to 0.5%.

In implementations, the polymer sub-layer further includes a solvent material. The solvent material may be, for example, 2-methoxy-monomethyl ether and other solvents that can dissolve a polymer.

In some embodiments, a thickness of the polymer sub-layer is greater than or equal to 20 nanometers and less than or equal to 50 nanometers.

A thickness of the quantum dot sub-layer is greater than or equal to 20 nanometers and less than or equal to 50 nanometers.

In some embodiments, the first transport layer includes an electron transport layer. The first electrode is a cathode and the second electrode is an anode. That is the quantum dot light emitting device is a light emitting device of an inverted structure.

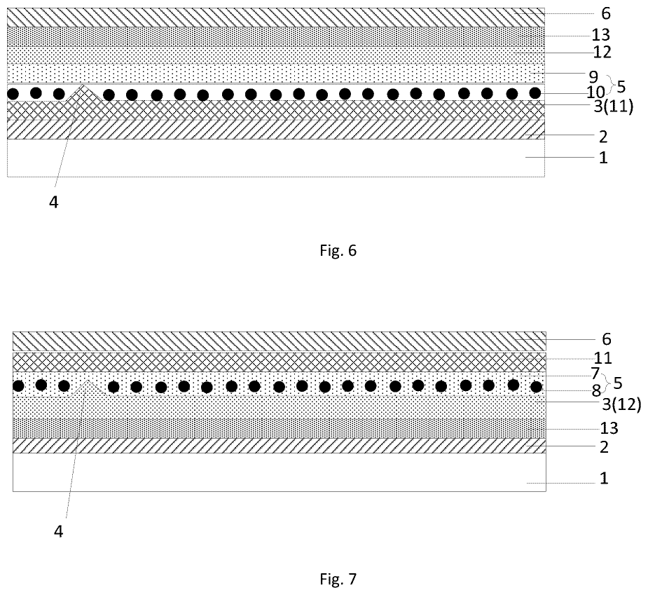

In some embodiments, as shown in FIGS. 4, 5 and 6, in a case that the first transport layer 3 includes an electron transport layer 11, the quantum dot light emitting device further includes a hole transport layer 12 located between the polymer quantum dot layer 5 and the second electrode 6, and a hole injection layer 13 located between the hole transport layer 12 and the second electrode 6.

Alternatively, in some embodiments, the first transport layer includes a hole transport layer. The first electrode is an anode and the second electrode is a cathode.

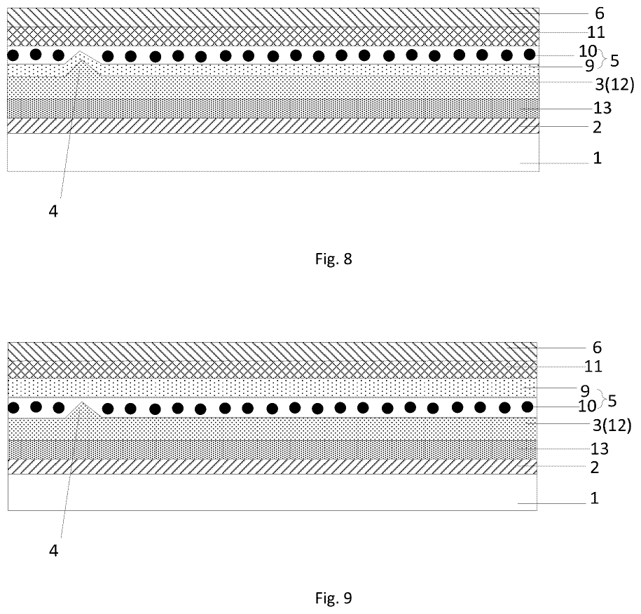

In some embodiments, as shown in FIGS. 7, 8 and 9, in a case that the first transport layer 3 includes a hole transport layer 12, the quantum dot light emitting device further includes an electron transport layer 11 located between the polymer quantum dot layer 5 and the second electrode 6, and a hole injection layer 13 located between the hole transport layer 12 and the first electrode 2.

According to the quantum dot light emitting device provided in embodiments of the present disclosure, no matter whether the first transport layer includes an electron transport layer or a hole transport layer since the polymer quantum dot layer including a polymer is provided, and the polymer materials can fill gaps of quantum dots, direct contact between the electron transport layer and the hole transport layer by bypassing the polymer quantum dot layer can be avoided. Thus, a large leakage current of the quantum dot light emitting device can be avoided, carrier balance of the quantum dot light emitting device can be improved, and light emitting efficiency of the quantum dot light emitting device can be increased.

In some embodiments, the polymer material is in contact with the electron transport layer and the hole transport layer in areas of at least some bump shapes.

During implementations, no matter whether the first transport layer includes the electron transport layer or the hole transport layer the polymer material can avoid the direct contact between the electron transport layer and the hole transport layer in areas of the bump shapes. That is the polymer material separates the electron transport layer from the hole transport layer Thus, a large leakage current of the quantum dot light emitting device can be avoided, carrier balance of the quantum dot light emitting device can be improved, and light emitting efficiency of the quantum dot light emitting device can be increased.

In some embodiments, the polymer material is insulated.

In some embodiments, a dipole is provided in a molecule of the polymer material.

In this way, positive and negative charge centers of the molecule of the polymer material are separated. The molecule can further adjust an interface barrier potential to a certain extent. In a case that the first transport layer includes an electron transport layer the polymer can further block the electron. The polymer quantum dot layer can prevent a large number of electrons from being enriched at an interface between the electron transport layer and the polymer quantum dot layer such that carrier balance of the quantum dot light emitting device can be improved.

In some embodiments, the polymer material includes one or a combination of polyethyleneimine ethoxylated (PEIE), 2-methoxy-N-(3-methyl-2-oxo-1,2,3,4-tetrahydroquinazolin-6-yl) benzene sulfonamide (PFI), 9,9-dioctyl fluorene-9,9-bis(N,N-dimethylaminopropyl) fluorene (PFN), poly(9,9-di-octylfluorenyl-2,7-diyl) (PFO), polymethyl methacrylate (PMMA) and polystyrene (PS).

In some embodiments, a band gap of the polymer material is greater than 3.5 electronvolts.

In some embodiments, the substrate may be glass or a flexible polyethylene terephthalate (PET) substrate. The cathode may include a transparent material such as indium tin oxide (ITO), fluorine-doped tin oxide (FTO) conductive glass or a conductive polymer, or may include a non-transparent material such as aluminum or silver. A material of the anode may include aluminum, silver, indium zinc oxide (IZO), etc. A material of the electron transport layer includes, for example, zinc oxide (ZnO) or ZnO doped with magnesium (Mg), aluminum (Al), zirconium (Zr), yttrium (Y), etc.

In some embodiments, a thickness of the electron transport layer is greater than or equal to 40 nanometers and less than or equal to 300 nanometers. For example, the thickness of the electron transport layer is 60 nanometers. A thickness of the hole injection layer is greater than or equal to 3 nanometers and less than or equal to 10 nanometers. For example, the thickness of the hole injection layer is 5 nanometers. A thickness of each of the anode and the cathode is greater than or equal to 10 nanometers and less than or equal to 100 nanometers.

In some embodiments, the hole transport layer includes a first hole transport layer and a second hole transport layer located between the first hole transport layer and the polymer quantum dot layer which are stacked. A thickness of the first hole transport layer is greater than 0 and less than or equal to 10 nanometers, and a thickness of the second hole transport layer is greater than 20 nanometers and less than or equal to 60 nanometers. A highest occupied molecular orbital (HOMO) energy level of the first hole transport layer is greater than or equal to −5.5 electronvolts and less than or equal to −6.2 electronvolts. A HOMO energy level of the second hole transport layer is greater than or equal to −5.1 electronvolts and less than or equal to −5.5 electronvolts. During implementations, a total thickness of the hole transport layer may be, for example, 35 nanometers, the thickness of the first hole transport layer is 5 nanometers, and the thickness of the second hole transport layer is 30 nanometers.

In some embodiments, root-mean-square surface roughness of a surface of a side of the polymer quantum dot layer facing away from the substrate is less than root-mean-square surface roughness of a surface of a side of the first transport layer facing away from the substrate.

In some embodiments, the root-mean-square surface roughness of the surface of the side of the first transport layer facing away from the substrate is greater than or equal to 5 nanometers and less than or equal to 15 nanometers.

In some embodiments, the surface of the side of the first transport layer facing away from the first electrode has a plurality of bump shapes.

A maximum height of the bump shape is greater than or equal to 10 nanometers and less than or equal to 50 nanometers.

In some embodiments, root-mean-square surface roughness of the surface of the side of the polymer quantum dot layer facing away from the first transport layer is greater than or equal to 0.59 nanometer and less than or equal to 2.25 nanometers.

Next, with an example in which an electron transport layer is used as the first transport layer and PEIE is used as the polymer material, test results of the quantum dot light emitting device provided in embodiments of the present disclosure are illustrated.

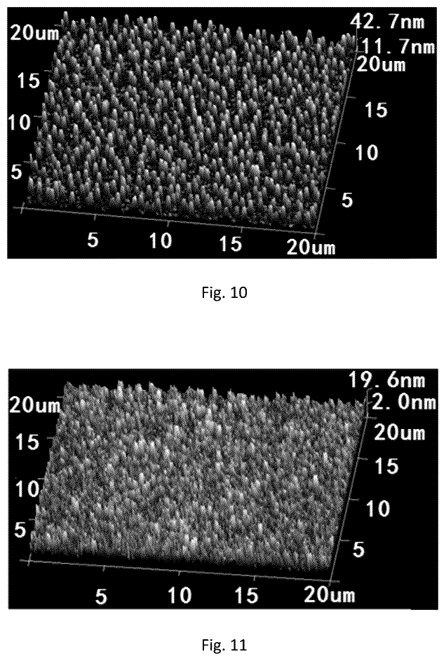

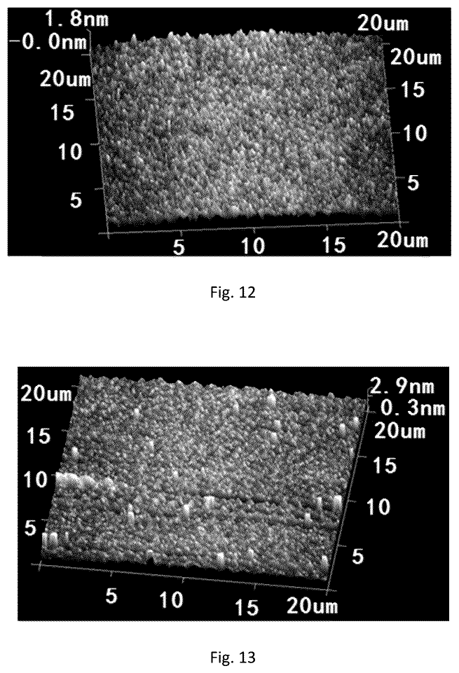

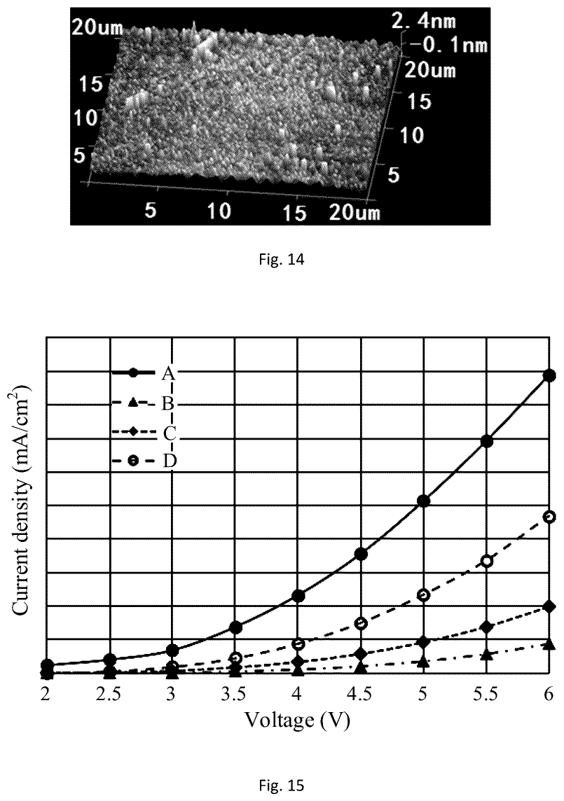

Before the polymer quantum dot layer is formed, appearance of the electron transport layer is as shown in FIG. 10. A surface of the electron transport layer has plenty of spikes, that is, bump shapes. A maximum height of the spike in FIG. 10 is 42.7 nanometers. Root-mean-square surface roughness (Rq) of the surface of the electron transport layer as shown in FIG. 10 is 10.1 nanometers. In the related art, surface appearance after a quantum dot layer is directly formed on the surface of the electron transport layer is as shown in FIG. 11. The spikes on the surface of the electron transport layer are partially covered with the quantum dot layer but some still pierce the quantum dot layer A maximum height of the spike is 19.6 nanometers, and Rq is 5.2 nanometers. In a solution that the polymer material and the quantum dot material are located in the same film layer after the polymer quantum dot layer is formed on the surface of the electron transport layer surface appearance of a side of the polymer quantum dot layer facing away from the electron transport layer is as shown in FIG. 12. Spikes on the surface are almost invisible, and Rq is 0.59 nanometer. In a solution that the quantum dot sub-layer is located between the electron transport layer and the polymer sub-layer after the polymer quantum dot layer is formed on the surface of the electron transport layer surface appearance of the side of the polymer quantum dot layer facing away from the electron transport layer is as shown in FIG. 13. Spikes on the surface are few, a maximum height of the spikes is 2.9 nanometers, and Rq is 2.25 nanometers. In a solution that the polymer sub-layer is located between the electron transport layer and the quantum dot sub-layer after the polymer quantum dot layer is formed on the surface of the electron transport layer surface appearance of the side of the polymer quantum dot layer facing away from the electron transport layer is as shown in FIG. 14. Spikes on the surface are few, a maximum height of the spikes is 2.4 nanometers, and Rq is 1.91 nanometers.

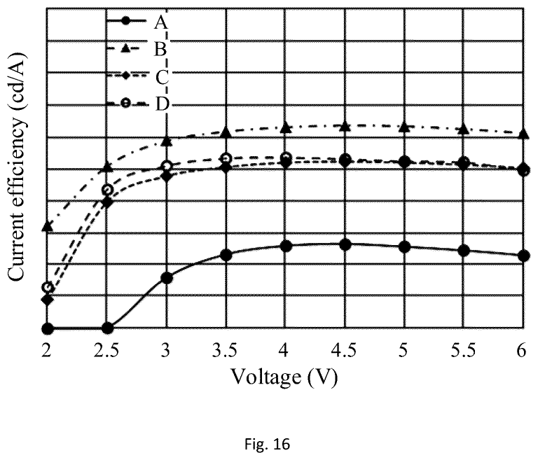

Voltage-current density curves and voltage-current efficiency curves of different quantum dot light emitting devices are as shown in FIGS. 15 and 16 respectively. In quantum dot light emitting device A, only the quantum dot layer is included between the electron transport layer and the hole transport layer Quantum dot light emitting devices B, C and D are quantum dot light emitting devices provided in embodiments of the present disclosure. In quantum dot light emitting device B, the polymer material and the quantum dot material are located in the same film layer. In quantum dot light emitting device C, the quantum dot sub-layer is located between the electron transport layer and the polymer sub-layer. In quantum dot light emitting device D, the polymer sub-layer is located between the electron transport layer and the quantum dot sub-layer. It can be seen from FIG. 15 that compared with quantum dot light emitting device A which only includes the quantum dot layer between the electron transport layer and the hole transport layer the quantum dot light emitting devices provided in embodiments of the present disclosure can reduce a leakage current. It can be seen from FIG. 16 that compared with quantum dot light emitting device A which only includes the quantum dot layer between the electron transport layer and the hole transport layer the quantum dot light emitting devices provided in embodiments of the present disclosure can greatly increase current efficiency such that light emitting efficiency of the quantum dot light emitting device can be increased. Quantum dot light emitting devices A, B, C and D are inverted OLED structures. That is an electron transport layer quantum dots, a hole transport layer a hole injection layer and an anode are manufactured on a cathode. In quantum dot light emitting devices A, B, C and D, the electron transport layer is a ZnO film layer formed through a sputtering process, and a thickness of the ZnO film layer is 60 nanometers. The hole transport layer and the hole injection layer are formed through an evaporation process. An anode is an Ag film layer formed through an evaporation process, and a thickness of the Ag film layer is 150 nanometers. A quantum dot layer in quantum dot light emitting device A is formed through spin-coating, and a thickness is 30 nanometers. In quantum dot light emitting devices B, C and D, polymer quantum dot layers are formed through spin-coating, and a thickness is 30 nanometers.

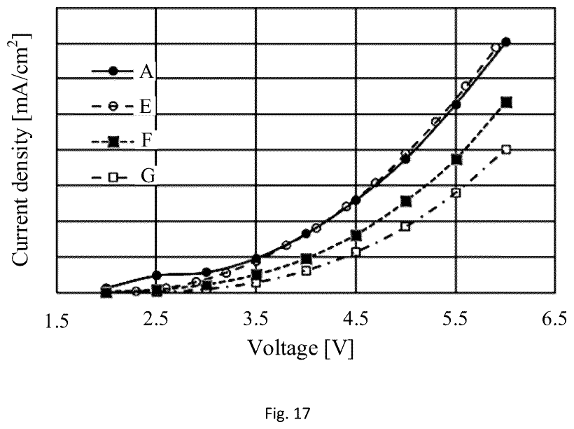

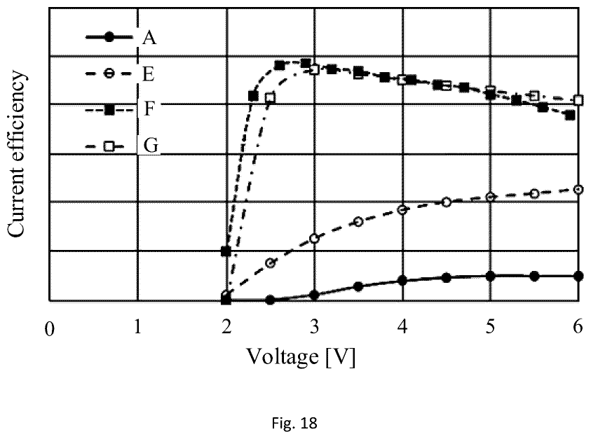

Voltage-current density curves and voltage-current efficiency curves of quantum dot light emitting devices having different mass fractions of polymer materials are as shown in FIGS. 17 and 18 respectively. In quantum dot light emitting device A, only the quantum dot layer is included between the electron transport layer and the hole transport layer That is a mass fraction of the polymer material is 0. Quantum dot light emitting devices E, F and G are quantum dot light emitting devices provided in embodiments of the present disclosure. Polymer materials and quantum dot materials in quantum dot light emitting devices E, F and G are located in the same film layer but mass fractions of the polymer materials in quantum dot light emitting devices E, F and G are different. A mass fraction of PEIE in quantum dot light emitting device E is 0.01%, a mass fraction of PEIE in quantum dot light emitting device F is 0.05%, and a mass fraction of PEIE in quantum dot light emitting device G is 0.1%. It can be seen from FIG. 17 that current density of the quantum dot light emitting device can be reduced by increasing the mass fraction of PEIE. It can be seen from FIG. 18 that in cases that the mass fractions of PEIE are 0.05% and 0.1%, current efficiency of the quantum dot light emitting device is better.

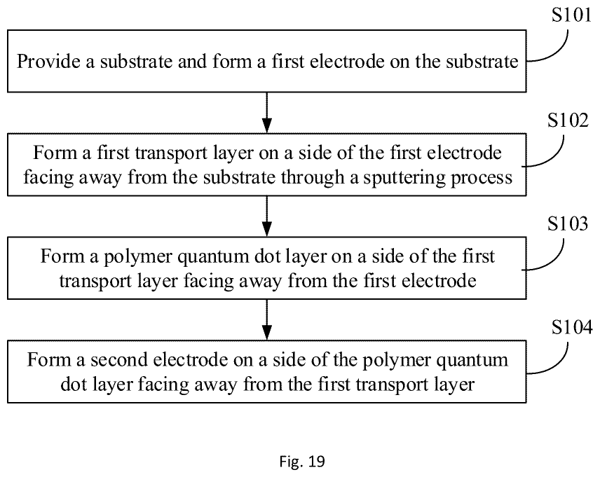

On the basis of the same inventive concept, embodiments of the present disclosure further provide a manufacturing method for a quantum dot light emitting device. As shown in FIG. 19, the method includes:
S101: provide a substrate and form a first electrode on the substrate.
S102: form a first transport layer on a side of the first electrode facing away from the substrate through a sputtering process. A surface of a side of the first transport layer facing away from the first electrode has a bump shape.
S103: form a polymer quantum dot layer on a side of the first transport layer facing away from the first electrode. The polymer quantum dot layer includes a polymer material and a quantum dot material.
S104: form a second electrode on a side of the polymer quantum dot layer facing away from the first transport layer.

According to the manufacturing method for a quantum dot light emitting device provided in embodiments of the present disclosure, since the polymer quantum dot layer is formed on the side of the first transport layer facing away from the first electrode, and the polymer material of the polymer quantum dot layer can cover the bump shape on the surface of the first transport layer a large leakage current of the quantum dot light emitting device caused by looseness of a quantum dot film layer in a case that only the quantum dot film layer is arranged is avoided. Thus, carrier balance of the quantum dot light emitting device can be improved, and light emitting efficiency of the quantum dot light emitting device can be increased.

In some embodiments, S103 of forming a polymer quantum dot layer on the side of the first transport layer facing away from the first electrode includes:
provide the polymer material and the quantum dot material, and mix the polymer material and the quantum dot material; and
deposit the polymer material and the quantum dot material that are mixed on the side of the first transport layer facing away from the first electrode, and form the polymer quantum dot layer.

In some embodiments, S103 of forming a polymer quantum dot layer on the side of the first transport layer facing away from the first electrode includes:
provide the polymer material, dissolve the polymer material in a solvent, and obtain a polymer solution;
coat the side of the first transport layer facing away from the first electrode with the polymer solution, and form a polymer sub-layer and
deposit a quantum dot material on a side of the polymer sub-layer facing away from the first transport layer and form a quantum dot sub-layer.

In some embodiments, S103 of forming a polymer quantum dot layer on the side of the first transport layer facing away from the first electrode includes:
deposit the quantum dot material on the side of the first transport layer facing away from the first electrode, and form a quantum dot sub-layer;
dissolve the polymer material in a solvent, and obtain a polymer solution; and
coat a side of the quantum dot sub-layer facing away from the first transport layer with the polymer solution, and form a polymer sub-layer.

In some embodiments, S102 of forming a first transport layer on a side of the first electrode facing away from the substrate through a sputtering process includes:
form an electron transport layer on the side of the first electrode facing away from the substrate through a magnetron sputtering process.

Before the step of forming a second electrode on a side of the polymer quantum dot layer facing away from the first transport layer the method further includes:
form a hole transport layer on the side of the polymer quantum dot layer facing away from the first transport layer and
form a hole injection layer on a side of the hole transport layer facing away from the polymer quantum dot layer.

Alternatively, in some embodiments, S102 of forming a first transport layer on a side of the first electrode facing away from the substrate through a sputtering process includes:
form a hole injection layer on the side of the first electrode facing away from the substrate; and
form a hole transport layer on a side of the hole injection layer facing away from the first electrode through a magnetron sputtering process.

Before the step of forming a second electrode on a side of the polymer quantum dot layer facing away from the first transport layer the method further includes:
form an electron transport layer on a side of the polymer quantum dot layer facing away from the first transport layer.

Next, with an example in which a first transport layer includes an electron transport layer a manufacturing method for a quantum dot light emitting device provided in embodiments of the present disclosure is illustrated.

In some embodiments, the manufacturing method for a quantum dot light emitting device includes steps as follows.
S201: deposit a material of a first electrode on a substrate, and form a first electrode.
S202: form an electron transport layer on the side of the first electrode facing away from the substrate through a magnetron sputtering process.

During implementations, for example, magnetron sputtering may be carried out in an argon (Ar) environment at power of 100 W, and a flux of the magnetron sputtering process is 40 sccm.
S203: provide PEIE and a quantum dot material, uniformly mix PEIE and the quantum dot material, and obtain a mixed polymer quantum dot material; and deposit the polymer quantum dot material on a side of the electron transport layer facing away from the first electrode, and form a polymer quantum dot layer.

During implementations, for example, a polymer quantum dot material may be deposited through an inkjet printing process, such that a polymer quantum dot layer is formed.
S204: deposit a hole transport layer and a hole injection layer in sequence on a side of the polymer quantum dot layer facing away from the electron transport layer.

During implementations, for example, the hole transport layer and the hole injection layer may be deposited through an evaporation process.
S205: form a second electrode on a side of the hole injection layer facing away from the hole transport layer.

During implementations, the second electrode may be formed through a magnetron sputtering process.

In some embodiments, the manufacturing method for a quantum dot light emitting device includes steps as follows.

S301: deposit a material of a first electrode on a substrate, and form a first electrode.

S302: form an electron transport layer on the side of the first electrode facing away from the substrate through a magnetron sputtering process.

During implementations, for example, magnetron sputtering may be carried out in an argon (Ar) environment at power of 100 W, and a flux of the magnetron sputtering process is 40 sccm.

S303: deposit a quantum dot material on a side of the electron transport layer facing away from the first electrode, and form a quantum dot sub-layer.

S304: dissolve PEIE in 2-methoxymonomethyl ether, carry out spin-coating on a side of the quantum dot sub-layer facing away from the electron transport layer at a rotational speed of 3000 rpm for 30 s, and carry out annealing at 120° C. for 10 min-20 min, and form a polymer sub-layer.

S305: deposit a hole transport layer and a hole injection layer in sequence on a side of the polymer sub-layer facing away from the quantum dot sub-layer.

S306: form a second electrode on a side of the hole injection layer facing away from the hole transport layer.

During implementations, the second electrode may be formed through a magnetron sputtering process.

In some embodiments, the manufacturing method for a quantum dot light emitting device includes steps as follows.

S401: deposit a material of a first electrode on a substrate, and form a first electrode.

S402: form an electron transport layer on the side of the first electrode facing away from the substrate through a magnetron sputtering process.

During implementations, for example, magnetron sputtering may be carried out in an argon (Ar) environment at power of 100 W, and a flux of the magnetron sputtering process is 40 sccm.

S403: dissolve PEIE in 2-methoxymonomethyl ether, carry out spin-coating on a side of the electron transport layer facing away from the first electrode at a rotational speed of 3000 rpm for 30 s, and carry out annealing at 120° C. for 10 min-20 min, and form a polymer sub-layer.

S404: deposit a quantum dot material on a side of the polymer sub-layer facing away from the electron transport layer and form a quantum dot sub-layer.

S405: deposit a hole transport layer and a hole injection layer in sequence on a side of the quantum dot sub-layer facing away from the polymer sub-layer.

S406: form a second electrode on a side of the hole injection layer facing away from the hole transport layer.

During implementations, the second electrode may be formed through a magnetron sputtering process.

Embodiments of the present disclosure provide a display panel. The display panel includes a plurality of quantum dot light emitting devices provided in embodiments of the present disclosure.

During implementations, the display panel includes a plurality of sub-pixels, and the sub-pixels include quantum dot light emitting devices.

During implementations, the sub-pixels include, for example, red sub-pixels, blue sub-pixels and green sub-pixels. The red sub-pixels include red quantum dot light emitting devices, the blue sub-pixels include blue quantum dot light emitting devices, and the green sub-pixels include green quantum dot light emitting devices. Quantum dot materials in the red quantum dot light emitting devices are red quantum dot materials, quantum dot materials in the blue quantum dot light emitting devices are blue quantum dot materials, and quantum dot materials in the green quantum dot light emitting devices are green quantum dot materials.

Embodiments of the present disclosure provide a display apparatus. The display apparatus includes the display panel provided in embodiments of the present disclosure.

The display apparatus provided in embodiments of the present disclosure may be a mobile phone, a tablet computer, a television, a monitor, a notebook computer, a digital photo frame, a navigator or other products or components having display functions. Other essential components of the display apparatus would be understood by those of ordinary skill in the art, will not be repeated herein and should not be regarded as a limitation on the present disclosure. Reference can be made to the above embodiments of the quantum dot light emitting device for implementation of the display apparatus, and repetition will not be described herein.

In summary, according to the quantum dot light emitting device and the manufacturing method therefor, the display panel and the display apparatus provided in embodiments of the present disclosure, since the polymer quantum dot layer is formed on the side of the first transport layer facing away from the first electrode, and the polymer material of the polymer quantum dot layer can cover the bump shape on the surface of the first transport layer a large leakage current of the quantum dot light emitting device caused by looseness of a quantum dot film layer in a case that only the quantum dot film layer is arranged is avoided. Thus, carrier balance of the quantum dot light emitting device can be improved, and light emitting efficiency of the quantum dot light emitting device can be increased.

Although the preferred embodiments of the present disclosure have been described, those skilled in the art can make additional changes and modifications to these embodiments once they learn the basic inventive concept. Therefore, the appended claims are intended to be interpreted as including the preferred embodiments and all changes and modifications falling within the scope of the present disclosure.

Apparently, those skilled in the art can make various modifications and variations to embodiments of the present disclosure without departing from the spirit and scope of the embodiments of the present disclosure. In this way, if these modifications and variations of embodiments of the present disclosure fall within the scope of the claims of the present disclosure and their equivalent technologies, the present disclosure is also intended to include these modifications and variations.

1. A quantum dot light emitting device, comprising:
a substrate;
a first electrode on a side of the substrate;
a first transport layer on a side of the first electrode facing away from the substrate;
wherein a surface of a side of the first transport layer facing away from the first electrode is provided with a bump shape;
a polymer quantum dot layer which is located on the side of the first transport layer facing away from the first electrode and comprises a polymer material and a quantum dot material; and
a second electrode on a side of the polymer quantum dot layer facing away from the first transport layer.

2. The quantum dot light emitting device according to claim 1, wherein root-mean-square surface roughness of a surface of a side of the polymer quantum dot layer facing away from the substrate is less than root-mean-square surface roughness of a surface of a side of the first transport layer facing away from the substrate.

3. The quantum dot light emitting device according to claim 2, wherein the root-mean-square surface roughness of the surface of the side of the first transport layer facing away from the substrate is greater than or equal to 5 nanometers and less than or equal to 15 nanometers; and
root-mean-square surface roughness of a surface of the side of the polymer quantum dot layer facing away from the first transport layer is greater than or equal to 0.59 nanometer and less than or equal to 2.25 nanometers.

4. The quantum dot light emitting device according to claim 2, wherein the surface of the side of the first transport layer facing away from the first electrode is provided with a plurality of bump shapes; and
a height of the bump shape is greater than or equal to 10 nanometers and less than or equal to 50 nanometers.

5. (canceled)

6. The quantum dot light emitting device according to claim 1, wherein the polymer material and the quantum dot material are in a same film layer.

7. The quantum dot light emitting device according to claim 6, wherein a mass fraction of the polymer material in the polymer quantum dot layer is greater than or equal to 0.02% and less than or equal to 0.5%.

8. The quantum dot light emitting device according to claim 6, wherein a thickness of the polymer quantum dot layer is greater than or equal to 20 nanometers and less than or equal to 50 nanometers.

9. The quantum dot light emitting device according to claim 1, wherein the polymer quantum dot layer comprises a polymer sub-layer comprising the polymer material and a quantum dot sub-layer comprising the quantum dot material, which are stacked;
wherein the polymer sub-layer is between the quantum dot sub-layer and the first transport layer or the quantum dot sub-layer is between the polymer sub-layer and the first transport layer.

10. (canceled)

11. (canceled)

12. The quantum dot light emitting device according to claim 9, wherein a mass fraction of the polymer material in the polymer sub-layer is greater than or equal to 0.02% and less than or equal to 0.5%.

13. The quantum dot light emitting device according to claim 9, wherein a thickness of the polymer sub-layer is greater than or equal to 20 nanometers and less than or equal to 50 nanometers; and
a thickness of the quantum dot sub-layer is greater than or equal to 20 nanometers and less than or equal to 50 nanometers.

14. The quantum dot light emitting device according to claim 1, wherein a dipole is provided in a molecule of the polymer material.

15. The quantum dot light emitting device according to claim 14, wherein the polymer material comprises one or a combination of polyethyleneimine ethoxylated, 2-methoxy-N-(3-methyl-2-oxo-1,2,3,4-tetrahydroquinazolin-6-yl) benzene sulfonamide, 9,9-dioctyl fluorene-9,9-bis(N,N-dimethylaminopropyl) fluorene, poly(9,9-di-octylfluorenyl-2,7-diyl), polymethyl methacrylate and polystyrene.

16. The quantum dot light emitting device according to claim 1, wherein a band gap of the polymer material is greater than 3.5 electronvolts.

17. The quantum dot light emitting device according to claim 1, wherein:
the first transport layer comprises an electron transport layer; and
the quantum dot light emitting device further comprises a hole transport layer between the polymer quantum dot layer and the second electrode, and a hole injection layer between the hole transport layer and the second electrode; or
the first transport layer comprises a hole transport layer and the quantum dot light emitting device further comprises an electron transport layer between the polymer quantum dot layer and the second electrode, and a hole injection layer between the hole transport layer and the first electrode.

18. (canceled)

19. The quantum dot light emitting device according to claim 17, wherein the polymer material is in contact with the electron transport layer and the hole transport layer in areas of at least some bump shapes.

20. A manufacturing method for a quantum dot light emitting device, comprising:
providing a substrate and forming a first electrode on the substrate;
forming a first transport layer on a side of the first electrode facing away from the substrate through a sputtering process; wherein a surface of a side of the first transport layer facing away from the first electrode is provided with a bump shape;
forming a polymer quantum dot layer on the side of the first transport layer facing away from the first electrode; wherein the polymer quantum dot layer comprises a polymer material and a quantum dot material; and
forming a second electrode on a side of the polymer quantum dot layer facing away from the first transport layer.

21. The method according to claim 20, wherein said forming a polymer quantum dot layer on the side of the first transport layer facing away from the first electrode comprises:
providing the polymer material and the quantum dot material, and mixing the polymer material and the quantum dot material; and
depositing the polymer material and the quantum dot material that are mixed on the side of the first transport layer facing away from the first electrode, and forming the polymer quantum dot layer.

22. The method according to claim 20, wherein said forming a polymer quantum dot layer on the side of the first transport layer facing away from the first electrode comprises:
providing the polymer material, dissolving the polymer material in a solvent, and obtaining a polymer solution;
coating the side of the first transport layer facing away from the first electrode with the polymer solution, and forming a polymer sub-layer; and
depositing the quantum dot material on a side of the polymer sub-layer facing away from the first transport layer and forming a quantum dot sub-layer; or
depositing the quantum dot material on the side of the first transport layer facing away from the first electrode, and forming a quantum dot sub-layer dissolving the polymer material in a solvent, and obtaining a polymer solution; and coating a side of the quantum dot sub-layer facing away from the first transport layer with the polymer solution, and forming a polymer sub-layer.

23. (canceled)

24. A display panel comprising a plurality of quantum dot light emitting devices according to claim 1.

25. A display apparatus, comprising the display panel according to claim 24.
